(19) United States
(12) Patent Application Publication
(10) Pub. No.: US 2024/0186463 A1
(43) Pub. Date: Jun. 6, 2024

(54) QUANTUM DOT LIGHT-EMITTING DEVICE, MANUFACTURING METHOD THEREOF AND DISPLAY DEVICE

(71) Applicants: Beijing BOE Technology Development Co., Ltd., Beijing (CN); BOE TECHNOLOGY GROUP CO., LTD., Beijing (CN)

(72) Inventor: Xiaoyuan ZHANG, Beijing (CN)

(21) Appl. No.: 17/795,218

(22) PCT Filed: Sep. 30, 2021
(86) PCT No.: PCT/CN2021/122113

§ 371 Date: Jul. 25, 2022

(51) Int. Cl. H01L 33/50; H01L 25/075; H01L 33/00; H01L 33/26; H01L 33/42

(52) U.S. Cl. CPC H01L 33/502; H01L 25/0753; H01L 33/005; H01L 33/26; H01L 33/42

(57) ABSTRACT

The present disclosure provides a quantum dot light-emitting device, a manufacturing method thereof and a display device, belongs to the field of display technology, and can solve problems of low luminous efficiency, unstable performance and short service life of conventional quantum dot light-emitting devices. The quantum dot light-emitting device of the present disclosure includes: a first electrode, a hole transport layer, a quantum dot light-emitting layer, an electron transport layer and a second electrode, which are sequentially stacked, and materials of the hole transport layer, the quantum dot light-emitting layer and the electron transport layer are all inorganic materials; and the hole transport layer includes a first hole transport layer and a second hole transport layer which are sequentially stacked, the first hole transport layer is at a side close to the first electrode, and a material of the second hole transport layer includes an inorganic perovskite material.

### TECHNICAL FIELD

The present disclosure belongs to the field of display technology, and particularly relates to a quantum dot light-emitting device, a manufacturing method thereof and a display device.

### BACKGROUND

A quantum dot light emitting diode (QLED) is an electroluminescent device, in which holes and electrons are driven by an external electric field to pass an interface barrier to enter a valence band energy level and a conduction band energy level of a quantum dot light-emitting layer respectively, and release photons to emit light when returning to a stable ground state from an excited state. The QLED has been developed rapidly in recent years due to its excellent characteristics of narrow emission spectrum, high color purity, and wide color gamut of emitted light.

In an existing quantum dot light-emitting device, a hole transport layer is usually made of an organic hole transport material, an electron transport layer is usually made of an inorganic electron transport material which has high mobility and has an energy level highly matched with quantum dots. The hole transport material has lower mobility, and has an energy level less matched with a quantum dot material than the electron transport layer side, resulting in the fact that electrons are usually more than holes in the quantum dot light-emitting device, and the extra electrons can easily charge the quantum dot material to cause fluorescence quenching and non-radiative recombination light emission. Moreover, the organic hole transport material is easily corroded by water vapor and the like, and thus has poor stability, which leads to poor overall stability and short service life of the quantum dot light-emitting device.

### SUMMARY

To solve at least one of the technical problems in the prior art, the present disclosure provides a quantum dot light-emitting device, a manufacturing method thereof and a display device.

In a first aspect, embodiments of the present disclosure provide a quantum dot light-emitting device, including: a first electrode, a hole transport layer, a quantum dot light-emitting layer, an electron transport layer and a second electrode, which are sequentially stacked, wherein materials of the hole transport layer, the quantum dot light-emitting layer and the electron transport layer are all inorganic materials; and the hole transport layer includes a first hole transport layer and a second hole transport layer which are sequentially stacked, the first hole transport layer is at a side close to the first electrode, and a material of the second hole transport layer includes an inorganic perovskite material.

In an embodiment, a structural formula of the inorganic perovskite material is: ABX₃; where A includes any one or more of Rb and Cs, B includes any one or more of Pb, Sn, Ge, Bi, Cu and Mn, and X includes any one or more of Cl, Br and I.

In an embodiment, the first hole transport layer is also used as a hole injection layer.

In an embodiment, a band gap of the inorganic perovskite material is larger than or equal to a band gap of an inorganic quantum dot material; and a highest occupied molecular orbital energy level of the inorganic perovskite material is higher than a highest occupied molecular orbital energy level of the inorganic quantum dot material and lower than a highest occupied molecular orbital energy level of an inorganic hole transport material.

In an embodiment, a thickness of the second hole transport layer ranges from 5 nm to 50 nm.

In an embodiment, an inorganic hole transport material contained in the first hole transport layer includes any one or more of NiO, NiMgO, MoOₓ, CuI, CuSCN, VOₓ and WOₓ.

In an embodiment, an inorganic electron transport material contained in the electron transport layer includes any one or more of ZnO, ZnMgO, ZnALOₓ, SnO₂ and TiO₂.

In an embodiment, an inorganic quantum dot material contained in the quantum dot light-emitting layer includes any one or more of CdS, CdSe, ZnSe, InP, PbS, CdS/ZnS, CdSe/ZnS, InP/ZnS and PbS/ZnS.

In an embodiment, a material of the first electrode includes any one or more of ITO and IZO; and a material of the second electrode includes any one or more of Al, Ag, Ti and Mo.

In an embodiment, the quantum dot light-emitting device further includes: a base substrate; and
the base substrate is on a side of the first electrode facing away from the quantum dot light-emitting layer; or the base substrate is on a side of the second electrode facing away from the quantum dot light-emitting layer.

In an embodiment, the quantum dot light-emitting device further includes: an electron blocking layer and a hole blocking layer;
the electron blocking layer is between the second hole transport layer and the quantum dot light-emitting layer; and
the hole blocking layer is between the electron transport layer and the quantum dot light-emitting layer.

In an embodiment, the quantum dot light-emitting device includes: a red quantum dot light-emitting device, a green quantum dot light-emitting device, or a blue quantum dot light-emitting device.

In a second aspect, the embodiments of the present disclosure provide a display device, including the quantum dot light-emitting device described above.

In a third aspect, the embodiments of the present disclosure provide a manufacturing method of a quantum dot light-emitting device, including:
depositing an inorganic hole transport material on a first electrode to form a first hole transport layer;
depositing an inorganic perovskite material on the first hole transport layer to form a second hole transport layer;
depositing an inorganic quantum dot material on the second hole transport layer to form a quantum dot light-emitting layer;
depositing an inorganic electron transport material on the quantum dot light-emitting layer to form an electron transport layer; and
forming a second electrode on the electron transport layer by deposition.

In an embodiment, depositing the inorganic perovskite material on the first hole transport layer to form the second hole transport layer includes:
dissolving a first inorganic material and a second inorganic material in a first organic solvent, and filtering to form a perovskite precursor solution, with a structural formula of the first inorganic material being AX, a structural formula of the second inorganic material including BX2, A including any one or more of Rb and Cs, B including any one or more of Pb, Sn, Ge, Bi, Cu and Mn, and X including any one or more of Cl, Br and I; and
depositing the perovskite precursor solution on the first hole transport layer to form the second hole transport layer.

In an embodiment, depositing the inorganic hole transport material on the first electrode to form the first hole transport layer includes:
dissolving the inorganic hole transport material in a second organic solvent to form an inorganic hole transport material solution; and
depositing the inorganic hole transport material solution on the first electrode to form the first hole transport layer.

### BRIEF DESCRIPTION OF DRAWINGS

FIG. 1 is a schematic structural diagram of an exemplary quantum dot light-emitting device;

FIG. 2 is a schematic structural diagram of a quantum dot light-emitting device according to the embodiments of the present disclosure:

FIG. 3 is a schematic diagram illustrating an energy level relationship of a quantum dot light-emitting device according to the embodiments of the present disclosure:

FIG. 4 is a schematic structural diagram of another quantum dot light-emitting device according to the embodiments of the present disclosure:

FIG. 5 is a flowchart illustrating a manufacturing method of a quantum dot light-emitting device according to the embodiments of the present disclosure:

FIG. 6a is a schematic diagram of current-voltage characteristics of a quantum dot light-emitting device according to the embodiments of the present disclosure and a comparative quantum dot light-emitting device:

FIG. 6b is a schematic diagram of brightness-voltage characteristics of the quantum dot light-emitting device according to the embodiments of the present disclosure and the comparative quantum dot light-emitting device:

FIG. 6c is a schematic diagram of efficiency-voltage characteristics of the quantum dot light-emitting device according to the embodiments of the present disclosure and the comparative quantum dot light-emitting device; and

FIG. 7 is a schematic diagram of transient spectra of the quantum dot light-emitting device according to the embodiments of the present disclosure and the comparative quantum dot light-emitting device.

### DETAIL DESCRIPTION OF EMBODIMENTS

In order to enable those skilled in the art to better understand the technical solutions of the present disclosure, the present disclosure is further described in detail below with reference to the drawings and specific embodiments.

Unless otherwise defined, technical terms or scientific terms used herein should have general meanings that are understood by those of ordinary skills in the technical field of the present disclosure. The words “first”, “second” and the like used herein do not denote any order, quantity or importance, but are just used to distinguish between different elements. Similarly, the words “one”, “a”, “the” and the like do not indicate a limitation to quantity, but indicate the existence of “at least one” instead. The word “include”, “comprise” or the like indicates that an element or object before the word encompasses the elements, objects or the equivalents thereof listed after the word, rather than excluding other elements or objects. The words “connect”, “couple” and the like are not restricted to physical or mechanical connection, but may also indicate electrical connection, whether direct or indirect. The words “on”, “under”, “left”, “right” and the like are only used to indicate relative positional relationships. When an absolute position of an object described is changed, the relative positional relationships may also be changed accordingly.

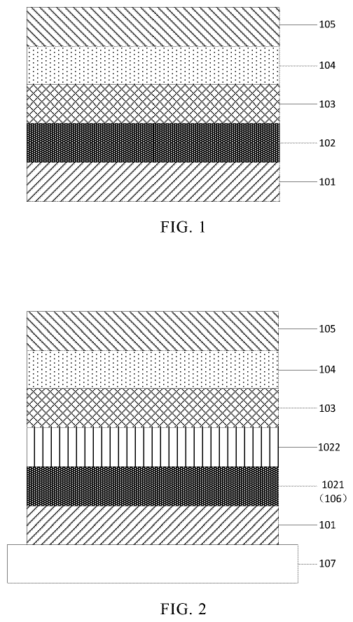

FIG. 1 is a schematic structural diagram of an exemplary quantum dot light-emitting device. As shown in FIG. 1, the quantum dot light-emitting device includes: a first electrode 101, a hole transport layer 102, a quantum dot light-emitting layer 103, an electron transport layer 104 and a second electrode 105, which are sequentially stacked. In the existing quantum dot light-emitting device, the hole transport layer 102 is usually made of an organic hole transport material such as PEDOT:PSS, TFB, PVK or the like, and the electron transport layer 104 is usually made of an inorganic electron transport material which has high mobility and has an energy level highly matched with quantum dots, such as ZnO, ZnMgO or the like. Since the organic hole transport material has lower mobility and has an energy level less matched with a quantum dot material than the electron transport layer 104 side, electrons are usually more than holes in the quantum dot light-emitting device, and the extra electrons can easily charge the quantum dot material to cause fluorescence quenching and non-radiative recombination light emission. Moreover, the organic hole transport material is easily corroded by water vapor and the like, and thus has poor stability, which leads to poor overall stability and short service life of the quantum dot light-emitting device. Some inorganic hole transport materials such as NiO, NiMgO, MoOₓ, CuI, CuSCN, VOₓ and WOₓ have been developed in order to increase hole mobility of the hole transport material of the hole transport layer 102, but thin films made from these inorganic hole transport materials have many surface defects, and direct contact of the thin films with the quantum dot light-emitting layer 103 can easily cause fluorescence quenching of the quantum dots, which reduces fluorescence quantum efficiency.

In order to solve at least one of the above technical problems, the embodiments of the present disclosure provide a quantum dot light-emitting device, a manufacturing method thereof, and a display device. The quantum dot light-emitting device, the manufacturing method thereof, and the display device provided by the embodiments of the present disclosure will be further described in detail below with reference to specific embodiments and the drawings.

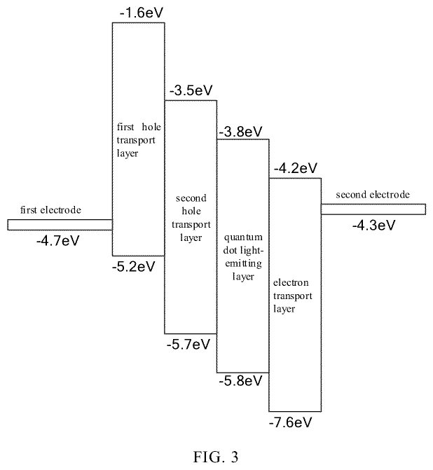

The embodiments of the present disclosure provide a quantum dot light-emitting device, and FIG. 2 is a schematic structural diagram of the quantum dot light-emitting device according to the embodiments of the present disclosure. As shown in FIG. 2, the quantum dot light-emitting device includes: a first electrode 101, a hole transport layer 102, a quantum dot light-emitting layer 103, an electron transport layer 104 and a second electrode 105, which are sequentially stacked, and materials of the hole transport layer 102, the quantum dot light-emitting layer 103 and the electron transport layer 104 are all inorganic materials; and the hole transport layer 102 includes a first hole transport layer 1021 and a second hole transport layer 1022 which are sequentially stacked, the first hole transport layer 1021 is located at a side close to the first electrode 101, and a material of the second hole transport layer 1022 includes an inorganic perovskite material.

The first electrode 101 may be an anode of the quantum dot light-emitting device, the anode may be made of a high power function electrode material, and may be of a single-layer structure or a multi-layer composite structure, for example, the anode may be made of a transparent material such as indium tin oxide (ITO), indium zinc oxide (IZO) or the like, or may be formed by sandwiching a metal material with good conductivity between two ITO layers, and the metal material may be any one of aluminum (Al), silver (Ag), titanium (Ti) and molybdenum (Mo), or any alloy thereof.

The second electrode 105 has a polarity opposite to that of the first electrode 101, and may be a cathode of the quantum dot light-emitting device, and the cathode may be made of a metal material, for example, the cathode may be made of any one of metal materials such as lithium (Li), aluminum (Al), magnesium (Mg) and silver (Ag), or any alloy thereof.

When a voltage is applied between the first electrode 101 and the second electrode 105, holes pass through the first hole transport layer 1021 and the second hole transport layer 1022 and reach the quantum dot light-emitting layer 103, electrons pass through the electron transport layer 104 and reach the quantum dot light-emitting layer 103, the holes and the electrons form excitons in the quantum dot light-emitting layer 103, and the formed excitons can perform energy level transition in the quantum dot light-emitting layer 103 to release energy, thereby emitting light.

In the quantum dot light-emitting device provided by the embodiments of the present disclosure, materials of the first hole transport layer 1021, the second hole transport layer 1022, the quantum dot light-emitting layer 103, and the electron transport layer 104 are all inorganic materials, so that the whole quantum dot light-emitting device has an inorganic material structure resistant to corrosion of water vapor and the like, which can improve overall stability of the quantum dot light-emitting device, thereby prolonging a service life of a quantum dot material. Moreover, the material of the first hole transport layer 1021 includes an inorganic hole transport material capable of effectively increasing mobility of the holes, and the inorganic perovskite material of the second hole transport layer 1022 can further increase the mobility of the holes, so that mobility of the holes at one side of the quantum dot light-emitting layer 103 is matched with mobility of the electrons at the other side of the quantum dot light-emitting layer 103, which avoids generation of many extra electrons and thus prevents an inorganic quantum dot material of the quantum dot material layer 103 from being charged to cause fluorescence quenching and non-radiative recombination light emission, thereby increasing luminous efficiency of the quantum dot light-emitting device. Furthermore, since the second hole transport layer 1022 is located between the first hole transport layer 1021 and the quantum dot light-emitting layer 103, and the material of the second hole transport layer 1022 is the inorganic perovskite material having good bipolar conductivity, the second hole transport layer 1022 can separate the first hole transport layer 1021 containing the inorganic hole transport material from the quantum dot light-emitting layer 103 containing the inorganic quantum dot material, so that fluorescence quenching of quantum dots caused by direct contact between the first hole transport layer 1021 and the quantum dot light-emitting layer 103 can be reduced or avoided, thereby improving fluorescence quantum efficiency and the luminous efficiency of the quantum dot light-emitting device.

In some embodiments, a structural formula of the inorganic perovskite material is: ABX₃; where A includes any one or more of Rb and Cs, B includes any one or more of Pb, Sn, Ge, Bi, Cu and Mn, and X includes any one or more of Cl, Br and I.

It should be noted that A may be a monovalent inorganic alkali metal ion, which may specifically be Rb, Cs, or the like, B may be a divalent inert metal ion, which may specifically be Pb, Sn, Ge, Bi, Cu, Mn, or the like, and X may be a halogen ion. A, B, X are not limited to the above ions, and may be specifically selected according to specific situations.

In some embodiments, the first hole transport layer 1021 is also used as a hole injection layer 106.

In practical applications, a main function of the hole injection layer 106 is to reduce a hole injection barrier and increase hole injection efficiency. The second hole transport layer 1022 needs to be connected to the first electrode 101 through the hole injection layer 106. Since the inorganic hole transport material of the first hole transport layer 1021 has good hole transport capability, the first hole transport layer 1021 can be also used as the hole injection layer 106, which obviates the need to independently dispose the hole injection layer 106 for the quantum dot light-emitting device, so that the number of layers in the quantum dot light-emitting device can be reduced, thereby reducing an overall thickness of the quantum dot light-emitting device, facilitating thinning of the quantum dot light-emitting device and thinning of a display device, and improving user experience. The first hole transport layer 1021 may have a thickness of 5 nm to 20 nm, and may be formed by an evaporation process.

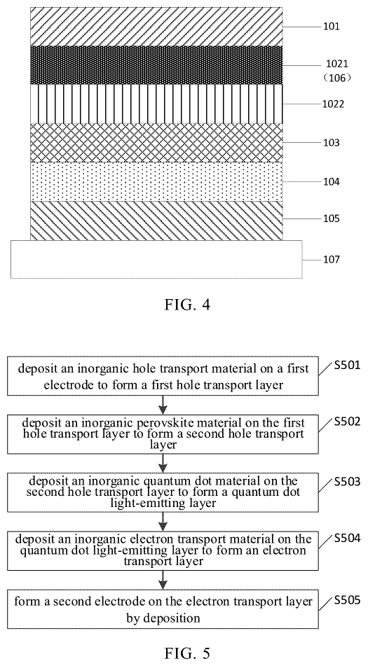

In some embodiments, FIG. 3 is a schematic diagram illustrating an energy level relationship of a quantum dot light-emitting device according to the embodiments of the present disclosure. As shown in FIG. 3, a band gap of the inorganic perovskite material is larger than or equal to that of the inorganic quantum dot material; and a highest occupied molecular orbital (HOMO) energy level of the inorganic perovskite material is higher than that of the inorganic quantum dot material and is lower than that of the inorganic hole transport material.

On one side of the quantum dot light-emitting layer 103, the band gap of the inorganic perovskite material is larger than or equal to that of the inorganic quantum dot material, the HOMO energy level of the inorganic perovskite material is higher than that of the inorganic quantum dot material and is lower than that of the inorganic hole transport material, so that it can be ensured that the holes are transported at a high speed from the first hole transport layer 1021 to the quantum dot light-emitting layer 103 through the second hole transport layer 1022. Correspondingly, on the other side of the quantum dot light-emitting layer 103, a band gap of an inorganic electron transport material is smaller than or equal to that of the inorganic quantum dot material, an HOMO energy level of the inorganic electron transport material is lower than that of the inorganic quantum dot material, so that it can be ensured that the electrons are transported at a high speed from the electron transport layer 104 to the quantum dot light-emitting layer 103. In this way, the holes and the electrons may form excitons in the quantum dot light-emitting layer 103, and the formed excitons may perform energy level transition in the quantum dot light-emitting layer 103 to release energy, thereby emitting light.

In some embodiments, a thickness of the second hole transport layer 1022 is from 5 nm to 50 nm.

In practical applications, the thickness of the second hole transport layer 1022 may be set in a range of 5 nm to 50 nm to be matched with thicknesses of the other layers in the quantum dot light-emitting device, so as to ensure the mobility of the holes. The specific thickness of the second hole transport layer 1022 may be set according to actual needs and is not limited here.

In some embodiments, the inorganic hole transport material contained in the first hole transport layer 1021 includes one or more of NiO, NiMgO, MoOₓ, CuI, CuSCN, VOₓ and WOₓ.

The inorganic hole transport material of the second hole transport layer 1022 has good hole transport performance, and may specifically be NiO, CuSCN, VOₓ, WOₓ, or the like, so that it can be ensured that the holes are efficiently and rapidly transported, thereby improving the mobility of the holes. The second hole transport layer 1022 may have a thickness of 10 nm to 100 nm, and may be formed by an evaporation process.

In some embodiments, the inorganic electron transport material contained in the electron transport layer 104 includes any one or more of ZnO, ZnMgO, ZnALOₓ, SnO₂ and TiO₂.

The inorganic electron transport material of the electron transport layer 104 has good electron transport performance, and may specifically be ZnO, ZnMgO, ZnALOₓ, SnO₂, TiO₂, or the like, so that it can be ensured that the electrons are efficiently and rapidly transported, thereby improving the mobility of the electrons. The electron transport layer 104 may have a thickness of 20 nm to 100 nm, and may be formed by an evaporation process.

In some embodiments, the inorganic quantum dot material contained in the quantum dot light-emitting layer 103 includes any one or more of CdS, CdSe, ZnSe, InP, PbS, CdS/ZnS, CdSe/ZnS, InP/ZnS and PbS/ZnS.

It should be noted that the inorganic quantum dot material has good luminous performance, and may specifically be any one or more of CdS, CdSe, ZnSe, InP, PbS, CdS/ZnS, CdSe/ZnS, InP/ZnS and PbS/ZnS, and the inorganic quantum dot material may be reasonably selected according to actual needs, which is not limited here.

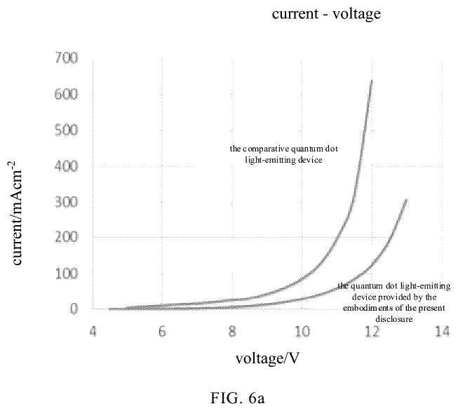

In some embodiments, as shown in FIG. 2, the quantum dot light-emitting device further includes: a base substrate 107; and the base substrate 107 is located on a side of the first electrode 101 facing away from the quantum dot light-emitting layer 103, so that an upright quantum dot light-emitting device is formed. FIG. 4 is a schematic structural diagram of another quantum dot light-emitting device according to the embodiments of the present disclosure. As shown in FIG. 4, the quantum dot light-emitting device shown in FIG. 4 is different from the quantum dot light-emitting device shown in FIG. 2 in that the base substrate 107 is located on a side of the second electrode 105 facing away from the quantum dot light-emitting layer 103 in the quantum dot light-emitting device shown in FIG. 4, so that an inverted quantum dot light-emitting device is formed. The quantum dot light-emitting device according to the embodiments of the present disclosure may be an upright quantum dot light-emitting device or an inverted quantum dot light-emitting device, so as to meet requirements of different display devices. A manufacturing process of the quantum dot light-emitting device will be described in detail below by taking the upright quantum dot light-emitting device as an example. It should be understood that a manufacturing process of the inverted quantum dot light-emitting device is the same as that of the upright quantum dot light-emitting device, and the only difference is that an order of forming the layers of the inverted quantum dot light-emitting device is different from that of forming the layers of the upright quantum dot light-emitting device, and will not be described separately.

In some embodiments, the quantum dot light-emitting device further includes: an electron blocking layer (not shown) and a hole blocking layer (not shown): the electron blocking layer is located between the second hole transport layer 1022 and the quantum dot light-emitting layer 103; and the hole blocking layer is located between the electron transport layer 104 and the quantum dot light-emitting layer 103.

Hole mobility of the electron blocking layer is generally greater than electron mobility thereof by 1 to 2 orders of magnitude, and the electron blocking layer is mainly used for transferring the holes, can effectively block transport of the electrons, and may be made of an inorganic material. A thickness of the electron blocking layer may be from 5 nm to 100 nm. Electron mobility of the hole blocking layer is generally greater than hole mobility thereof by 1 to 2 orders of magnitude, and the hole blocking layer is mainly used for transferring the electrons, can effectively block transport of the holes, and may be made of an inorganic material. A thickness of the hole blocking layer may be from 5 nm to 100 nm. It should be understood that the quantum dot light-emitting device according to the embodiments of the present disclosure further includes an electron injection layer and other conventional structures, which may be set according to the related technology and be manufactured by using a process in the related art, and will not be described in detail here.

In some embodiments, the quantum dot light-emitting device includes: a red quantum dot light-emitting device, a green quantum dot light-emitting device, or a blue quantum dot light-emitting device.

The red quantum dot light-emitting device, the green quantum dot light-emitting device and the blue quantum dot light-emitting device may be arranged in an array and emit red light, green light and blue light respectively, thereby realizing colorful display.

The embodiments of the present disclosure further provide a display device, which includes the quantum dot light-emitting device provided by any of the above embodiments. The display device may be an electronic device with a display function, such as a mobile phone, a tablet computer, an electronic watch, a sports bracelet or a notebook computer. Technical effects of the display device may be found in the above discussion of the technical effects of the quantum dot light-emitting device, and will not be repeated here.

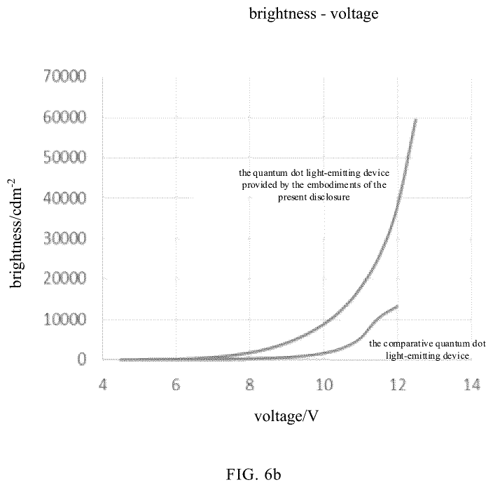

The embodiments of the present disclosure further provide a manufacturing method of a quantum dot light-emitting device, and FIG. 5 is a flowchart illustrating the manufacturing method of the quantum dot light-emitting device according to the embodiments of the present disclosure. As shown in FIG. 5, the manufacturing method of the quantum dot light-emitting device includes steps of:
S501, depositing an inorganic hole transport material on a first electrode to form a first hole transport layer;
S502, depositing an inorganic perovskite material on the first hole transport layer to form a second hole transport layer;
S503, depositing an inorganic quantum dot material on the second hole transport layer to form a quantum dot light-emitting layer;
S504, depositing an inorganic electron transport material on the quantum dot light-emitting layer to form an electron transport layer; and
S505, forming a second electrode on the electron transport layer by deposition.

Each step in the manufacturing method of the quantum dot light-emitting device according to the embodiments of the present disclosure is described in detail below by taking specific materials as examples.

### Embodiment One

In the present embodiment, for manufacturing the quantum dot light-emitting device, NiMgO is selected as an inorganic hole injection material, CsPbBr₃, which has an HOMO energy level between that of NiMgO and that of an inorganic quantum dot luminescent material and has a band gap larger than that of the inorganic quantum dot luminescent material, is selected as the inorganic hole transport material, a green light inorganic quantum dot material of CdSe/ZnS is selected as the inorganic quantum dot luminescent material, and ZnO is selected as the inorganic electron transport material. The steps of the manufacturing method include first depositing a NiMgO nanoparticle solution with a concentration of 15 mg/ml on a piece of cleaned ITO conductive glass (i.e., the first electrode), annealing at 135° C. for 10 minutes to obtain a thin film with a thickness of about 45 nm, then depositing a perovskite solution with a concentration of 58 mg/ml (0.1 mol/L) thereon, annealing at 120° C. for 10 minutes to obtain a perovskite thin film with a thickness of about 30 nm, subsequently, respectively depositing a solution of the quantum dot material with a concentration of 10 mg/ml and a ZnO solution with a concentration of 30 mg/ml, annealing at 120° C. for 10 minutes to obtain a quantum dot light-emitting layer with a thickness of about 30 nm and a ZnO electron transport layer with a thickness of about 45 nm, and finally transferring the device into a vacuum evaporator to form an Ag electrode (i.e., the second electrode) by deposition.

### Embodiment Two

In the present embodiment, for manufacturing the quantum dot light-emitting device, CuSCN is selected as the inorganic hole injection material, CsPbI₃, which has an HOMO energy level between that of CuSCN and that of the inorganic quantum dot luminescent material and has a band gap larger than that of the inorganic quantum dot luminescent material, is selected as the inorganic hole transport material, a red light inorganic quantum dot material of CdSe/ZnSe is selected as the inorganic quantum dot luminescent material, and ZnO is selected as the inorganic electron transport material. The steps of the manufacturing method include first depositing a CuSCN solution with a concentration of 25 mg/ml on a piece of cleaned ITO conductive glass (i.e., the first electrode), annealing at 120° C. for 20 minutes to obtain a CuSCN thin film with a thickness of about 50 nm, then depositing a perovskite solution with a concentration of 58 mg/ml (0.1 mol/L), annealing at 120° C. for 10 minutes to obtain a perovskite thin film with a thickness of about 30 nm, subsequently, respectively depositing a solution of the quantum dot material with a concentration of 10 mg/ml and a ZnO solution with a concentration of 30 mg/ml, annealing at 120° C. for 10 minutes to obtain a quantum dot light-emitting layer with a thickness of about 30 nm and a ZnO electron transport layer with a thickness of about 45 nm, and finally transferring the device into a vacuum evaporator to form an Ag electrode (i.e., the second electrode) by deposition.

In some embodiments, depositing the inorganic perovskite material on the first hole transport layer to form the second hole transport layer includes: dissolving a first inorganic material and a second inorganic material in a first organic solvent, and filtering to form a perovskite precursor solution, with a structural formula of the first inorganic material being AX, a structural formula of the second inorganic material including BX₂, A including any one or more of Rb and Cs, B including any one or more of Pb, Sn, Ge, Bi, Cu and Mn, and X including any one or more of Cl, Br and I; and depositing the perovskite precursor solution on the first hole transport layer to form the second hole transport layer.

Specifically, the perovskite material of CsPbBr₃ in Embodiment One is taken as an example. CsBr and PbBr₂ are respectively weighted and taken according a molar ratio of 1.7:1, and are respectively dissolved in anhydrous DMSO to obtain solutions with a concentration of 0.1 mol/L. The CsBr solution and the PbBr₂ solution are mixed together, and stirred to react at 60° C. overnight. The mixed solution is filtered with a PTFE filter membrane of 0.45 μm before use so as to form the perovskite precursor solution. Finally, the perovskite precursor solution is deposited on the first hole transport layer, and is dried to form the second hole transport layer containing CsPbBr₃.

In some embodiments, depositing the inorganic hole transport material on the first electrode to form the first hole transport layer includes: dissolving the inorganic hole transport material in a second organic solvent to form a solution of the inorganic hole transport material; and depositing the solution of the inorganic hole transport material on the first electrode to form the first hole transport layer.

Specifically, the inorganic hole transport material of CuSCN in Embodiment Two is taken as an example. 250 mg of CuSCN is weighted and taken, and dissolved in 10 ml of ethyl sulfide, and CuSCN and ethyl sulfide are mixed together through magnetic stirring, heated at 60° C. to be fully dissolved, and then cooled to form a CuSCN solution which is light yellow and has a concentration of 25 mg/ml. Finally, the CuSCN solution is deposited on the first electrode, and dried to form the first hole transport layer containing CuSCN.

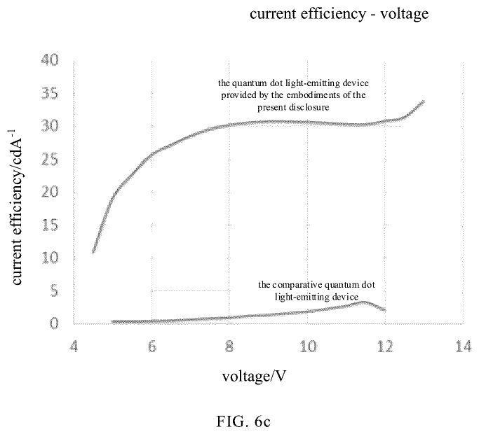

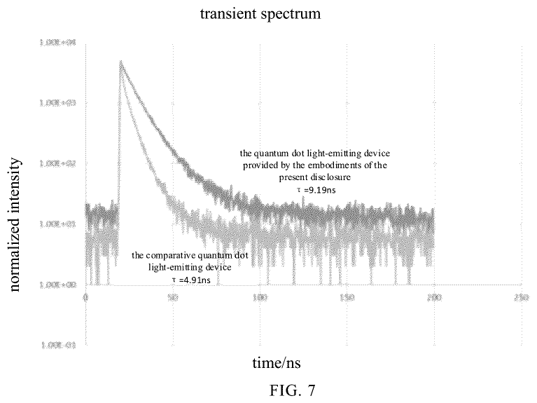

The performance of the quantum dot light-emitting device provided by the embodiments of the present disclosure is illustrated below by experimental test data. Specifically, the structure of the quantum dot light-emitting device in Embodiment One, that is, the device structure of ITO/NiMgO/CsPbBr₃/QD/ZnO/Ag, is taken as an example. Correspondingly, a structure of a comparative quantum dot light-emitting device is ITO/NiMgO/QD/ZnO/Ag, that is, a quantum dot light-emitting layer (QD) is in direct contact with a hole transport layer (NiMgO), and no inorganic perovskite material is disposed between the two layers. When the two quantum dot light-emitting devices are simultaneously tested in a same environment, results of current-voltage characteristics, brightness-voltage characteristics and efficiency-voltage characteristics of the two quantum dot light-emitting devices are respectively shown in FIG. 6a, FIG. 6b and FIG. 6c. It can be seen that when being applied with a same voltage, the quantum dot light-emitting device provided by the embodiments of the present disclosure has a smaller current, higher brightness and higher current efficiency than the comparative quantum dot light-emitting device. In another aspect, when thin films of the hole transport layer (NiMgO)/the quantum dot light-emitting layer (QD) of the comparative quantum dot light-emitting device and thin films of the first hole transport layer (NiMgO)/the second hole transport layer (CsPbBr₃)/the quantum dot light-emitting layer (QD) of the quantum dot light-emitting device provided by the embodiments of the present disclosure are simultaneously formed, transient spectra of the two quantum dot light-emitting devices are tested, so as to measure a change of a fluorescence lifetime of the inorganic quantum dot material before and after addition of the inorganic perovskite material to the comparative quantum dot light-emitting device, and the results are shown in FIG. 7. In the comparative quantum dot light-emitting device, since NiMgO is in direct contact with the inorganic quantum dot material, serious fluorescence quenching of quantum dots occurs due to surface defects, a fluorescence lifetime of the quantum dots is shorter, and device efficiency is very low. As for the quantum dot light-emitting device provided by the embodiments of the present disclosure, after the second hole transport layer formed of the perovskite material is added thereto, NiMgO and the inorganic quantum dot material are spaced apart from each other, so that reduction in a fluorescence lifetime of the quantum dot material is less, and efficiency of the quantum dot light-emitting device is greatly improved.

It should be understood that the above embodiments are merely exemplary embodiments adopted to illustrate the principle of the present disclosure, and the present disclosure is not limited thereto. Various modifications and improvements can be made by those of ordinary sill in the art without departing from the spirit and essence of the present disclosure, and those modifications and improvements are also considered to fall within the scope of the present disclosure.

1. A quantum dot light-emitting device, comprising: a first electrode, a hole transport layer, a quantum dot light-emitting layer, an electron transport layer and a second electrode, which are sequentially stacked, wherein materials of the hole transport layer, the quantum dot light-emitting layer and the electron transport layer are all inorganic materials; and
the hole transport layer comprises a first hole transport layer and a second hole transport layer which are sequentially stacked, the first hole transport layer is at a side close to the first electrode, and a material of the second hole transport layer comprises an inorganic perovskite material.

2. The quantum dot light-emitting device of claim 1, wherein a structural formula of the inorganic perovskite material is: ABX₃; where A comprises any one or more of Rb and Cs, B comprises any one or more of Pb, Sn, Ge, Bi, Cu and Mn, and X comprises any one or more of Cl, Br and I.

3. The quantum dot light-emitting device of claim 1, wherein the first hole transport layer is also used as a hole injection layer.

4. The quantum dot light-emitting device of claim 1, wherein a band gap of the inorganic perovskite material is larger than or equal to a band gap of an inorganic quantum dot material; and a highest occupied molecular orbital energy level of the inorganic perovskite material is higher than a highest occupied molecular orbital energy level of the inorganic quantum dot material and lower than a highest occupied molecular orbital energy level of an inorganic hole transport material.

5. The quantum dot light-emitting device of claim 1, wherein a thickness of the second hole transport layer ranges from 5 nm to 50 nm.

6. The quantum dot light-emitting device of claim 1, wherein an inorganic hole transport material contained in the first hole transport layer comprises any one or more of NiO, NiMgO, MoOₓ, CuI, CuSCN, VOₓ and WOₓ.

7. The quantum dot light-emitting device of claim 1, wherein an inorganic electron transport material contained in the electron transport layer comprises any one or more of ZnO, ZnMgO, ZnALOₓ, SnO₂ and TiO₂.

8. The quantum dot light-emitting device of claim 1, wherein an inorganic quantum dot material contained in the quantum dot light-emitting layer comprises any one or more of CdS, CdSe, ZnSe, InP, PbS, CdS/ZnS, CdSe/ZnS, InP/ZnS and PbS/ZnS.

9. The quantum dot light-emitting device of claim 1, wherein a material of the first electrode comprises any one or more of ITO and IZO; and a material of the second electrode comprises any one or more of Al, Ag, Ti and Mo.

10. The quantum dot light-emitting device of claim 1, further comprising: a base substrate,
wherein the base substrate is on a side of the first electrode facing away from the quantum dot light-emitting layer; or the base substrate is on a side of the second electrode facing away from the quantum dot light-emitting layer.

11. The quantum dot light-emitting device of claim 1, further comprising: an electron blocking layer and a hole blocking layer;
wherein the electron blocking layer is between the second hole transport layer and the quantum dot light-emitting layer; and
the hole blocking layer is between the electron transport layer and the quantum dot light-emitting layer.

12. The quantum dot light-emitting device of claim 1, comprising: a red quantum dot light-emitting device, a green quantum dot light-emitting device, or a blue quantum dot light-emitting device.

13. A display device, comprising the quantum dot light-emitting device of claim 1.

14. A manufacturing method of a quantum dot light-emitting device, comprising:
depositing an inorganic hole transport material on a first electrode to form a first hole transport layer;
depositing an inorganic perovskite material on the first hole transport layer to form a second hole transport layer;
depositing an inorganic quantum dot material on the second hole transport layer to form a quantum dot light-emitting layer;
depositing an inorganic electron transport material on the quantum dot light-emitting layer to form an electron transport layer; and
forming a second electrode on the electron transport layer by deposition.

15. The manufacturing method of the quantum dot light-emitting device of claim 14, wherein depositing the inorganic perovskite material on the first hole transport layer to form the second hole transport layer comprises:
dissolving a first inorganic material and a second inorganic material in a first organic solvent, and filtering to form a perovskite precursor solution, with a structural formula of the first inorganic material being AX, a structural formula of the second inorganic material comprising BX₂, A comprising any one or more of Rb and Cs, B comprising any one or more of Pb, Sn, Ge, Bi, Cu and Mn, and X comprising any one or more of Cl, Br and I; and
depositing the perovskite precursor solution on the first hole transport layer to form the second hole transport layer.

16. The manufacturing method of the quantum dot light-emitting device of claim 14, wherein depositing the inorganic hole transport material on the first electrode to form the first hole transport layer comprises:
dissolving the inorganic hole transport material in a second organic solvent to form an inorganic hole transport material solution; and
depositing the inorganic hole transport material solution on the first electrode to form the first hole transport layer.
